(19) United States
(12) Patent Application Publication
(10) Pub. No.: US 2025/0311268 A1
(43) Pub. Date: Oct. 2, 2025

(54) SEMICONDUCTOR DEVICES AND FABRICATING METHODS THEREOF

(71) Applicant: YANGTZE MEMORY TECHNOLOGIES CO., LTD., Wuhan (CN)

(72) Inventors: Di Wang, Wuhan (CN); Wenxi Zhou, Wuhan (CN); Zhiliang Xia, Wuhan (CN); Wei Liu, Wuhan (CN); Zongliang Huo, Wuhan (CN)

(21) Appl. No.: 18/666,065

(22) Filed: May 16, 2024

Related U.S. Application Data
(63) Continuation of application No. PCT/CN2024/084121, filed on Mar. 27, 2024.

(51) Int. Cl. H01L 29/66; H01L 27/06; H01L 27/07; H01L 27/092; H01L 29/786

(52) U.S. Cl. CPC H10D 30/025; H10D 30/6757; H10D 84/813; H10D 84/85; H10D 88/00

(57) ABSTRACT

Semiconductor devices and fabricating methods thereof are provided. A semiconductor device including vertical transistors and storage units coupled with the vertical transistors correspondingly is provided. The vertical transistor includes a semiconductor layer and a gate structure. The semiconductor layer includes a vertical portion extending in a vertical direction and a first lateral portion extending from a first end of the vertical portion in a lateral direction. The gate structure is coupled to the vertical portion of the semiconductor layer and extends in the vertical direction. The first lateral portions of the semiconductor layers of two adjacent vertical transistors in the lateral direction are connected with each other.

### CROSS-REFERENCE TO RELATED APPLICATIONS

This application is a continuation of International Application No. PCT/CN2024/084121, filed on Mar. 27, 2024, which is hereby incorporated by reference in its entirety.

### TECHNICAL FIELD

The present disclosure generally relates to the field of semiconductor technology, and more particularly, to semiconductor devices and fabricating methods thereof.

### BACKGROUND

Planar memory cells are scaled to smaller sizes by improving process technology, circuit design, programming algorithm, and fabrication process. However, as feature sizes of the memory cells approach a lower limit, planar process, and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

In an aspect of the present disclosure, a semiconductor device including vertical transistors and storage units coupled with the vertical transistors correspondingly is provided. The vertical transistor includes a semiconductor layer and a gate structure. The semiconductor layer includes a vertical portion extending in a vertical direction and a first lateral portion extending from a first end of the vertical portion in a lateral direction. The gate structure is coupled to the vertical portion of the semiconductor layer and extends in the vertical direction. The first lateral portions of the semiconductor layers of two adjacent vertical transistors in the lateral direction are connected with each other.

In some implementations, the semiconductor layer has a U-shaped cross-section in a plane formed by the vertical direction and the lateral direction.

In some implementations, the semiconductor layer of the vertical transistor includes a second lateral portion extending from a second end of the vertical portion in the lateral direction, and the second lateral portion is coupled with the corresponding storage unit.

In some implementations, the storage unit includes a capacitor with a first electrode, a second electrode, and a dielectric layer between the first electrode and the second electrode. The first electrode is directly coupled with the second lateral portion of the semiconductor layer of the corresponding vertical transistor.

In some implementations, the second electrode includes a multiple-layer structure, each layer of the multiple-layer structure includes one of carbon, polysilicon, metal, metal compounds, and silicide.

In some implementations, two adjacent vertical transistors in the lateral direction are separated by an isolation structure, and the gate structure of the vertical transistor is positioned in a side of the vertical portion of the semiconductor layer opposite to the isolation structure.

In some implementations, the isolation structure includes a conductor layer and a dielectric layer surrounding the conductor layer.

In some implementations, the dielectric layer includes a first dielectric layer under the conductor layer, a second dielectric layer on the conductor layer, a left sidewall on the left of conductor layer to separate the conductor layer from a first vertical transistor on the left, and a right sidewall on the right of the conductor layer to separate the conductor layer from a second vertical transistor on the right.

In some implementations, the first dielectric layer, the second dielectric layer, the left sidewall, and the right sidewall include different materials.

In some implementations, the semiconductor device further includes bit lines extending in the lateral direction and directly coupled with the vertical transistors through the first lateral portions of the semiconductor layers of the vertical transistors.

In some implementations, the bit lines are coupled with the first lateral portions at a bottom of the semiconductor layers.

In some implementations, the semiconductor layer has a leakage value lower than a pico-ampere.

In some implementations, the semiconductor includes one or a combination of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn₂O, SnₓO, HfₓIn_{y}Zn_{z}O, GaₓZn_{y}Sn₂O, AlₓZn_{y}Sn₂O, YbₓGa_{y}Zn_{z}O, and InₓGa_{y}O.

In some implementations, the semiconductor device further includes a peripheral circuit stacked on the vertical transistors.

In some implementations, the semiconductor device further includes a pad-out interconnect layer stacked on the storage units.

In another aspect of the present disclosure, a method for forming a semiconductor device is provided. The method includes forming a cell hole on a substrate and then forming a dielectric layer of a capacitor in the cell hole, the cell hole is partly filled by the dielectric layer. The method further includes forming a first electrode of the capacitor covering the dielectric layer, the cell hole is fully filled by the first electrode. The method further includes forming a vertical transistor coupled with the first electrode and forming a second electrode of the capacitor surrounding the dielectric layer.

In some implementations, the substrate includes at least one mesh layer laminated with at least one sacrifice layer alternately. Forming the second electrode of the capacitor includes removing at least one sacrifice layer to form a cavity and filling the cavity with the second electrode of the capacitor.

In some implementations, filling the cavity with the second electrode of the capacitor includes forming a multiple-layer structure in the cavity. Each layer of the multiple layer structure includes one of carbon, polysilicon, metal, metal compounds, and silicide.

In some implementations, forming a vertical transistor coupled with the first electrode includes forming an isolation structure between two adjacent vertical transistors.

In some implementations, forming the isolation structure between two adjacent vertical transistors includes forming a first dielectric layer on the substrate, forming a conductor layer on the first dielectric layer, and forming a second dielectric layer on the conductor layer.

In some implementations, forming the isolation structure between two adjacent vertical transistors further includes forming a left sidewall on the left of conductor layer to separate the conductor layer from a first vertical transistor on the left and forming a right sidewall on the right of the conductor layer to separate the conductor layer from a second vertical transistor on the right.

In some implementations, the first dielectric layer, the second dielectric layer, the left sidewall, and the right sidewall include different materials.

In some implementations, forming a vertical transistor coupled with the first electrode includes forming a semiconductor layer covering the isolation structure. The semiconductor layer has a U-shaped cross-section in a plane formed by a vertical direction and a lateral direction.

In some implementations, the semiconductor layer includes a vertical portion of the first vertical transistor covering the left sidewall, a first lateral portion of the first vertical transistor covering the second dielectric layer, a vertical portion of the second vertical transistor covering the right sidewall, and a first lateral portion of the second vertical transistor covering the second dielectric layer.

In some implementations, before forming a vertical transistor coupled with the first electrode, further includes etching the first electrode to form a recess to accommodate the vertical transistor.

In some implementations, the method further includes forming a bit line extending in a lateral directly coupled with the vertical transistors through the first lateral portions of the semiconductor layers of the vertical transistors.

In some implementations, the bit line is coupled with the first lateral portions at a bottom of the semiconductor layers.

In some implementations, the method further includes forming a peripheral circuit stacked on the vertical transistor.

In some implementations, the method further includes forming a pad-out interconnect layer stacked on the capacitor.

In some implementations, the semiconductor layer has a leakage value lower than a pico-ampere.

In some implementations, the includes one or a combination of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O.

In still another aspect of the present disclosure, a semiconductor device including single-gate vertical transistors and storage units coupled with the single-gate vertical transistors correspondingly is provided. Two adjacent single-gate vertical transistors in a lateral direction are separated by an isolation structure and share a U-shaped semiconductor layer covering both sides of the isolation structure in the lateral direction. The gate structure of the single-gate vertical transistor is coupled with a side of the semiconductor layer opposite to the isolation structure.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a schematic circuit diagram of a semiconductor device including an array of memory cells each having a vertical transistor, according to some implementations of the present disclosure.

FIG. 2 illustrates a schematic side view of a cross-section of the vertical transistors and storage units of the semiconductor device, according to some implementations of the present disclosure.

FIG. 3 illustrates a flowchart of a fabricating method for forming the semiconductor device, according to some implementations of the present disclosure.

FIGS. 4A-40 each illustrates a schematic view of the semiconductor device at a certain fabricating stage of the method shown in FIG. 3, according to various implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be used in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

Transistors are used as the switch or selecting devices in the memory cells of some semiconductor devices, such as dynamic radon access memory (DRAM). In a one-transistor-one-capacitor (1T1C) DRAM structure, data is stored in the capacitors. There is a high requirement regarding the leakage issue of the selection transistors. Thus, it is necessary to identify alternative channel materials with lower leakage compared to using the monocrystalline silicon as the channel material. Moreover, with the continuous scaling development of DRAM, the unit size of each capacitor cell continues to decrease, the etching aspect ratio of the capacitors increases, causing serious challenges in the fabricating processes and increasing product cost.

To address one or more of the aforementioned issues, the present disclosure introduces a solution in which low-leakage materials, such as a metal oxide semiconductor material, are selected for use as the channel of the select transistors to solve the leakage problem in the process of DRAM scaling. The disclosed semiconductor devices include single-gate vertical transistors, and the shape and structure of the active area of each vertical transistor are redesigned to accommodate the low-leakage materials. The corresponding fabricating processes of the semiconductor devices are described, in which the semiconductor layers of two adjacent vertical transistors are connected and the capacitors can be formed before the transistors of the 1T1C DRAM structure, and the fabrication of the vertical transistor occurring in the middle of the fabrication of the capacitors. By using the new channel material of the selection transistors in DRAM and the corresponding new fabrication method, the disclosed semiconductor devices can have a high memory density with a further reduced cell size. The fabrication difficulty of the disclosed semiconductor devices is decreased by applying the disclosed capacitor fabricating process. The disclosed fabricating process can have a simplified procedure compared to existing methods, thereby reducing the product cost.

Consistent with the scope of the present disclosure, according to some implementations of the present disclosure, each vertical transistor includes a semiconductor layer extending in a vertical direction and a gate structure beside the semiconductor layer. In some implementations, the word lines and the bit lines connected to the vertical transistors are arranged along a first lateral direction and a second lateral direction, respectively. Each semiconductor layer of a corresponding vertical transistor extends along a vertical direction. By using such an arrangement, memory area efficiency can be increased. Further, the memory cell array and the peripheral circuits can be formed separately on different wafers, such that the fabricating processes of the memory cell array and the peripheral circuits do not affect each other, thus the memory area efficiency can be further increased.

Consistent with the scope of the present disclosure, according to some implementations of the present disclosure, the semiconductor layers of two adjacent vertical transistors in the lateral direction are connected with each other, thus the channel length of each vertical transistor is extended. The short channel effect brought by the reduced feature size can thus be mitigated with an extended channel. Further, the dielectric layer and the first electrode of the capacitor are formed before the fabrication of the vertical transistors, and the second electrode of the capacitor is formed after the fabrication of the vertical transistors. The new fabrication method is compatible with high temperature processes, thus thermal budget of the fabrication process can be fully consumed.

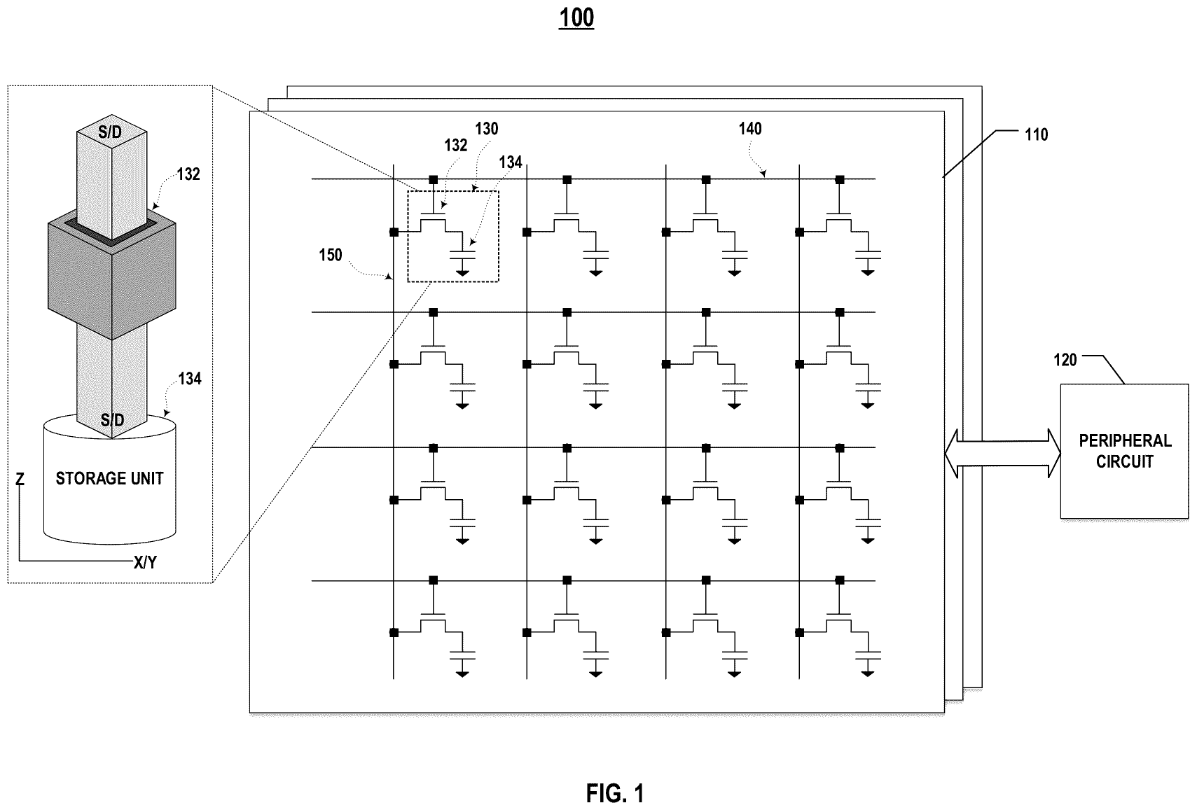

FIG. 1 illustrates a schematic diagram of a semiconductor device 100 including peripheral circuits and an array of memory cells each having a vertical transistor, according to some aspects of the present disclosure. Semiconductor device 100 can include a memory cell array 110 and peripheral circuits 120 coupled to memory cell array 110. Memory cell array 110 can be any suitable memory cell array in which each memory cell 130 includes a vertical transistor 132 and a storage unit 134 coupled to vertical transistor 132. In some implementations, memory cell array 110 is a DRAM cell array, and storage unit 134 is a capacitor for storing charge as the binary information stored by the respective DRAM cell. As shown in FIG. 1, memory cells 130 can be arranged in a two-dimensional (2D) array having rows and columns. Peripheral circuits 120 can include any suitable digital, analog, and/or mixed-signal circuits used for facilitating the operations of the memory cell array. For example, the peripheral circuit can include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits in first semiconductor structure 210 use complementary metal-oxide-semiconductor (CMOS) technology, e.g., which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations. Semiconductor device 100 can include word lines 140 coupling peripheral circuits 120 and memory cell array 110 for controlling the switch of vertical transistors 132 in memory cells 130 located in a row, as well as bit lines 150 coupling peripheral circuits 120 and memory cell array 110 for sending data to and/or receiving data from memory cells 130 located in a column. That is, each word line 140 is coupled to a respective row of memory cells 130, and each bit line 150 is coupled to a respective column of memory cells 130.

Consistent with the scope of the present disclosure, vertical transistors 132, such as vertical metal-oxide-semiconductor field-effect transistors (MOSFETs), can replace the conventional planar transistors as the pass transistors of memory cells 130 to reduce the area occupied by the pass transistors, the coupling capacitance, as well as the interconnect routing complexity, as described below in detail. As shown in FIG. 1, in some implementations, different from planar transistors in which the active regions are formed in the substrates, vertical transistor 132 includes a semiconductor body extending vertically (in the z-direction) above the substrate (not shown). That is, semiconductor body can extend above the top surface of the substrate, exposing not only the top surface of semiconductor body but also one or more of its side surfaces. As shown in FIG. 1, for example, semiconductor body can have a cuboid shape exposing four sides. It is understood that semiconductor body may take any suitable shape, such as polyhedron shapes or a cylinder shape. That is, the cross-section of semiconductor body in the plan view (e.g., in the x-y plane) can have a square shape, a rectangular shape (or a trapezoidal shape), a circular shape (or an oval shape), or any other suitable shapes. It is understood that consistent with the scope of the present disclosure, semiconductor layers that have a circular or oval shape of their cross-sections in the plan view may still be considered to have multiple sides, allowing the gate structures to be coupled with more than one side of the semiconductor layers. As described below with respect to the fabrication process, semiconductor body can be formed from the substrate (e.g., by etching or epitaxy), and thus, has the same semiconductor material (e.g., silicon crystalline silicon) as the substrate (e.g., a silicon substrate).

As shown in FIG. 1, vertical transistor 132 can also include a gate structure coupled with one or more sides of semiconductor body, i.e., in one or more planes of the side surface(s) of the active region. In other words, the active region of vertical transistor 132, i.e., semiconductor body, can be at least partially surrounded by gate structure. The gate structure can include a gate dielectric over one or more sides of semiconductor body, e.g., coupled with four side surfaces of semiconductor body as shown in FIG. 1. The gate structure can also include a gate electrode over and coupled with the gate dielectric. The gate dielectric can include any suitable dielectric materials, such as silicon oxide, silicon nitride, silicon oxynitride, or high-k dielectrics. The gate electrode can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides.

As shown in FIG. 1, vertical transistor 132 can further include a pair of a source and a drain (S/D, dope regions, a.k.a., source electrode and drain electrode) formed at the two ends of semiconductor body in the vertical direction (the z-direction), respectively. The source and drain can be doped with any suitable P-type dopants, such as boron (B) or Gallium (Ga), or any suitable N-type dopants, such as phosphorus (P) or arsenic (As). The source and drain can be separated by the gate structure in the vertical direction (the z-direction). As a result, one or more channels (not shown) of vertical transistor 132 can be formed in semiconductor body vertically between the source and drain when a gate voltage applied to the gate electrode of the gate structure exceeds the threshold voltage of vertical transistor 132.

In some implementations, as shown in FIG. 1, vertical transistor 132 is a multi-gate transistor. This means that the gate structure can be coupled with more than one side of semiconductor body (e.g., four sides in FIG. 1) to form more than one gate, allowing for the formation of multiple channels between the source and drain during operation. Unlike planar transistors that include only a single planar gate (resulting in a single planar channel), vertical transistor 132 shown in FIG. 1 can include multiple vertical gates on multiple sides of semiconductor body due to the semiconductor structure of the semiconductor body and the gate structure that surrounds the multiple sides of the semiconductor body. Compared with planar transistors, vertical transistor 132 shown in FIG. 1 can have a larger gate control area, enabling better channel control with a smaller subthreshold swing. During the off state, since the channel is fully depleted, the leakage current of vertical transistor 132 can be significantly reduced as well. As described in detail below, the multi-gate vertical transistors can include double-gate vertical transistors (e.g., dual-side gate vertical transistors), tri-gate vertical transistors (e.g., tri-side gate vertical transistors), and GAA vertical transistors.

While vertical transistor 132 is shown as a multi-gate transistor in FIG. 1, it is understood that the vertical transistors disclosed herein may also include single-gate transistors, as described in detail below. That is, gate structure may be coupled with a single side of semiconductor body, for example, for the purpose of increasing the transistor and memory cell density. It is also understood that while the gate dielectric is shown as being separate (i.e., a separate structure) from other gate dielectrics of adjacent vertical transistors (not shown), the gate dielectric may be part of a continuous dielectric layer having multiple gate dielectrics of vertical transistors.

As shown in FIG. 1, storage unit 134 can be coupled to the source or the drain of vertical transistor 132. Storage unit 134 can include any devices that are capable of storing binary data (e.g., 0 and 1), including but not limited to capacitors for DRAM cells and FRAM cells, as well as PCM elements for PCM cells. Peripheral circuits 120 can be coupled to memory cell array 110 through bit lines 150, word lines 140, and any other suitable metal wirings. As described above, peripheral circuits 120 can include any suitable circuits for facilitating the operations of memory cell array 110 by applying and sensing voltage signals and/or current signals through word lines 140 and bit lines 150 to and from each memory cell 130. Peripheral circuits 120 can include various types of peripheral circuits formed using CMOS technologies.

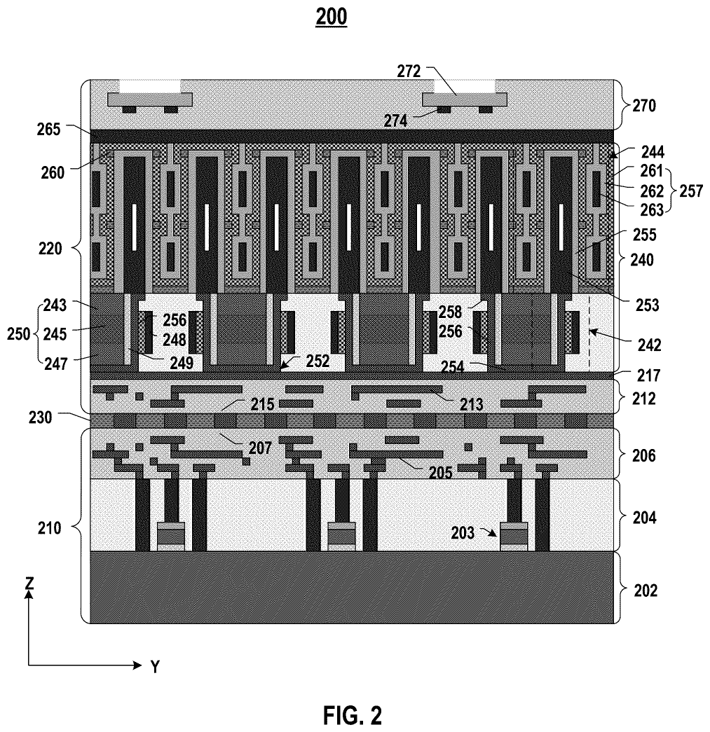

FIG. 2 illustrates a side view of a cross-section of a semiconductor device 200 including vertical transistors, according to some aspects of the present disclosure. It is understood that FIG. 2 is for illustrative purposes only and may not necessarily reflect the actual device structure (e.g., interconnections) in practice. In some implementations, semiconductor device 200 represents an example of a bonded chip. The components of semiconductor device 200 (e.g., memory cell array and peripheral circuits) can be formed separately on different substrates and then joined to form a bonded chip. Semiconductor device 200 can include a first semiconductor structure 210 including the peripheral circuits of a memory cell array. Semiconductor device 200 can also include a second semiconductor structure 220 including the memory cell array stacked over first semiconductor structure 210. First and second semiconductor structures 210 and 220 are jointed at bonding interface 230 therebetween, according to some implementations. As shown in FIG. 2, first semiconductor structure 210 can include a substrate 202, which can include silicon (e.g., single crystalline silicon, c-Si), silicon germanium (SiGe), gallium arsenide (GaAs), germanium (Ge), silicon-on-insulator (SOI), or any other suitable materials.

First semiconductor structure 210 can include peripheral circuits 204 on substrate 202. In some implementations, peripheral circuits 204 includes a plurality of transistors 203 (e.g., planar transistors and/or semiconductor transistors). Trench isolations (e.g., shallow trench isolations (STIs)) and doped regions (e.g., wells, sources, and drains of transistors 203) can be formed on or in substrate 202 as well.

In some implementations, first semiconductor structure 210 further includes an interconnect layer 206 above peripheral circuits 204 to transfer electrical signals to and from peripheral circuits 204. Interconnect layer 206 can include a plurality of interconnects (also referred to herein as “contacts”) including lateral interconnect lines and vertical interconnect access (VIA) contacts. As used herein, the term “interconnects” can broadly include any suitable types of interconnects, such as middle-end-of-line (MEOL) interconnects and back-end-of-line (BEOL) interconnects. Interconnect layer 206 can further include one or more interlayer dielectric (ILD) layers (also known as “intermetal dielectric (IMD) layers”) in which the interconnect lines and via contacts can form. That is, interconnect layer 206 can include interconnect lines and via contacts in multiple ILD layers. In some implementations, peripheral circuits 204 are coupled to one another through the interconnects in interconnect layer 206. The interconnects in interconnect layer 206 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 2, first semiconductor structure 210 can further include a bonding layer 207 at bonding interface 230 and above interconnect layer 206 and peripheral circuits 204. Bonding layer 207 can include a plurality of bonding contacts 205 and dielectrics electrically isolating bonding contacts 205. Bonding contacts 205 can include conductive materials, such as Cu. The remaining area of bonding layer 207 can be formed with dielectric materials, such as silicon oxide. Bonding contacts 205 and surrounding dielectrics in bonding layer 207 can be used for hybrid bonding. Similarly, as shown in FIG. 2, second semiconductor structure 220 can also include a bonding layer 215 at bonding interface 230 and above bonding layer 207 of first semiconductor structure 210. Bonding layer 215 can include a plurality of bonding contacts 213 and dielectrics electrically isolating bonding contacts 213. Bonding contacts 213 can include conductive materials, such as Cu. The remaining area of bonding layer 215 can be formed with dielectric materials, such as silicon oxide. Bonding contacts 213 and surrounding dielectrics in bonding layer 215 can be used for hybrid bonding. Bonding contacts 213 are coupled with bonding contacts 205 at bonding interface 230, according to some implementations.

Second semiconductor structure 220 can be bonded on top of first semiconductor structure 210 in a face-to-face manner at bonding interface 230. In some implementations, bonding interface 230 is disposed between bonding layers 215 and 207 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, bonding interface 230 is the place at which bonding layers 215 and 207 are met and bonded. In practice, bonding interface 230 can be a layer with a certain thickness that includes the top surface of bonding layer 207 of first semiconductor structure 210 and the bottom surface of bonding layer 215 of second semiconductor structure 220.

In some implementations, second semiconductor structure 220 further includes an interconnect layer 212 including bit lines 217 above bonding layer 215 to transfer electrical signals. Interconnect layer 212 can include a plurality of interconnects, such as MEOL interconnects and BEOL interconnects. In some implementations, the interconnects in interconnect layer 212 also include local interconnects, such as bit line contacts, word line contacts, and capacitor contacts. Interconnect layer 212 can further include one or more ILD layers in which the interconnect lines and via contacts can form. The interconnects in interconnect layer 212 can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

In some implementations, second semiconductor structure 220 includes a DRAM device in which memory cells are provided in the form of an array of DRAM cells 240 above interconnect layer 212 and bonding layer 215. That is, interconnect layer 212 including bit lines 217 can be disposed between bonding layer 215 and array of DRAM cells 240. It is understood that the cross-section of semiconductor device 200 in FIG. 2 may be made along the bit line direction (the y-direction), and one bit line 217 in interconnect layer 212 extending laterally in the y-direction may be coupled to a column of DRAM cells 240.

Each DRAM cell 240 can include a vertical transistor 242 and capacitor 244 coupled to the vertical transistor 242. DRAM cell 240 can be a 1T1C cell consisting of one transistor and one capacitor. It is understood that DRAM cell 240 may have any suitable configurations, such as 2T1C cell, 3T1C cell, etc.

Vertical transistor 242 can be a MOSFET used to switch a respective DRAM cell 240. In some implementations, vertical transistor 242 includes a semiconductor layer 252 (i.e., the active region in which multiple channels can form) extending vertically (in the z-direction), and a gate structure coupled with a plurality of sides of semiconductor layer 252. In some implementations, a leakage value of the semiconductor layer 252 is lower than a pico-ampere. For example, semiconductor layer 252 can include a metal oxide semiconductor material. In the present implementation, the semiconductor layer can be one or more of indium gallium zinc oxide (InₓGa_{y}Zn_{z}O), indium gallium silicon oxide (InₓGa_{y}Si_{z}O), indium stannum zinc oxide (InₓSn_{y}Zn_{z}O), indium zinc oxide (InₓZn_{y}O), zinc oxide (ZnₓO), zinc stannum oxide (ZnₓSn_{y}O), zinc oxide nitride (ZnₓO_{y}N), zirconium zinc stannum oxide (ZrₓZn_{y}Sn_{z}O), stannum oxide (SnₓO), hafnium indium zinc oxide (HfₓIn_{y}Zn_{z}O), gallium zinc stannum oxide (GaₓZn_{y}Sn_{z}O), aluminum zinc stannum oxide (AlₓZn_{y}Sn_{z}O), ytterbium gallium zinc oxide (YbₓGa_{y}Zn_{z}O), indium gallium oxide (InₓGa_{y}O), etc.

As shown in FIG. 2, in some implementations, semiconductor layer 252 includes a vertical portion 256 extending in a vertical direction (the z-direction), a first lateral portion 254 extending from a first end of vertical portion 256 in a lateral direction (the y-direction), and a second lateral portion 258 extending from a second end of vertical portion 256 in the lateral direction (the y-direction). First lateral portion 254 is coupled with bit line 217, and second lateral portion 258 is coupled with the corresponding storage unit 244. Referring to FIG. 2, two first lateral portions 258 of the semiconductor layers of two adjacent vertical transistors 242 in the lateral direction are interconnected, resulting a U-shaped cross-section of semiconductor layers 252 of two adjacent vertical transistors 242 in the y-z plane.

Vertical transistor 242 can further include a source and a drain disposed at the two ends (the upper end and lower end) of semiconductor layer 252, respectively, in the vertical direction (the z-direction). In some implementations, one of the source and drain is coupled to capacitor 244, and the other one of the source and drain is coupled to bit line 217. The source and drain can be doped with N-type dopants (e.g., Por As) or P-type dopants (e.g., B or Ga) at a desired doping level. As shown in FIG. 2, a contact area between capacitor 244 and vertical transistor 242 equals an area of second lateral portion 258 in the x-y plane, which is tens of times larger than an area of the second end of vertical portion 256 in the x-y plane. The contact resistance can be reduced significantly due to the increasement of contact area. In this scenario, a source node contact between capacitor 244 and vertical transistor 242 can be omitted. As shown in FIG. 2, the source or drain coupled to bit line 217 extends in the lateral direction (the y-direction). Bit line 217 may be formed directly on the laterally extending source or drain of vertical transistor 242, simplifying the fabrication process compared to coupling bit line 217 with the first end of vertical portion 256.

In some implementations, the gate structure includes a gate dielectric 256 and a gate electrode 248. In some implementations, gate dielectric 256 includes dielectric materials, such as silicon oxide, silicon nitride, or high-k dielectrics including, but not limited to, aluminum oxide (Al₂O₃), hafnium oxide (HfO₂), tantalum oxide (Ta₂O₅), zirconium oxide (ZrO₂), titanium oxide (TiO₂), or any combination thereof. In some implementations, gate electrode 248 includes conductive materials including, but not limited to W, Co, Cu, Al, TIN, TaN, polysilicon, silicide, or any combination thereof. In some implementations, gate electrode 248 includes multiple conductive layers, such as a W layer over a TiN layer. In one example, gate structure may be a “gate oxide/gate poly” gate in which gate dielectric 256 includes silicon oxide and gate electrode includes doped polysilicon. In another example, gate structure may be a high-k metal gate (HKMG) in which gate dielectric 256 includes a high-k dielectric and gate electrode includes a metal.

As described above, since gate electrode 248 may be part of a word line or extend in the word line direction (the x-direction) as a word line, although not directly shown in FIG. 2, second semiconductor structure 220 of semiconductor device 200 can also include a plurality of word lines each extending in the word line direction (the x-direction). Each word line can be coupled to a row of DRAM cells 240. That is, bit line 217 and word line can extend in two perpendicular lateral directions, and semiconductor layer 252 of vertical transistor 242 can extend in the vertical direction perpendicular to the two lateral directions in which bit line 217 and word line extend.

In some implementations, the rows of vertical transistors 242 separated by trench isolation 250 are mirror-symmetric to one another with respect to isolation structure 250, the gate structure of vertical transistor 242 is positioned in a side of vertical portion 256 of semiconductor layer 252 opposite to isolation structure 250. Isolation structure 250 can be formed with dielectric materials including, but not limited to, silicon oxide, silicon nitride, silicon oxynitride, low-k dielectrics, or any combination thereof. It is understood that isolation structure 250 may include an air gap each disposed laterally between adjacent semiconductor layers 252. As described below with respect to the fabrication process, air gaps may be formed due to the relatively small pitches of vertical transistors 242 in the bit line direction (e.g., the y-direction). On the other hand, the relatively large dielectric constant of air in air gaps (e.g., about 4 times the dielectric constant of silicon oxide) can improve the insulation effect between vertical transistors 242 compared with some dielectrics (e.g., silicon oxide).

In some implementations, isolation structure 250 includes a conductor layer 245 surrounded by a dielectric layer. The plurality of conductor layers 245 in semiconductor device 200 are connected to a common grand so that no charge can be accumulated between two adjacent vertical transistors 240, in this way, electrical coupling between the semiconductor layers 252 of two adjacent vertical transistor 240 can be greatly reduced. In some implementations, conductor layer 245 includes conductive materials including, but not limited to W, Co, Cu, Al, TiN, TaN, polysilicon, silicide, or any combination thereof. In some implementations, conductor layer 245 includes multiple conductive layers, such as a W layer over a TiN layer.

As shown in FIG. 2, the dielectric layer includes a first dielectric layer 243 under conductor layer 245, a second dielectric layer 247 on conductor layer 245, a left sidewall 249 on the left of conductor layer 245 to separate the conductor layer from a first vertical transistor on the left, and a right sidewall 249 (refers as 249 as well) on the right of conductor layer 245 to separate conductor layer 245 from a second vertical transistor on the right. That is, conductor layer 245 is surrounded by the dielectric layer to be isolated from the adjacent semiconductor layers 256. In some implementations, the dielectric layer includes dielectric materials, such as silicon oxide, silicon nitride, or high-k dielectrics including, but not limited to, aluminum oxide (Al₂O₃), hafnium oxide (HfO₂), tantalum oxide (Ta₂O₅), zirconium oxide (ZrO₂), titanium oxide (TiO₂), or any combination thereof. In some implementations, first dielectric layer 243, second dielectric layer 247, the left sidewall 249, and the right sidewall 249 comprise different materials.

As shown in FIG. 2, in some implementations, capacitor 244 includes a first electrode 253 above and coupled with the source or drain of vertical transistor 242, a capacitor dielectric 255 above and coupled with first electrode 253, and a second electrode 257 above and coupled with capacitor dielectric 255. That is, capacitor 244 can be a vertical capacitor in which first and second electrodes 253 and 257 and capacitor dielectric 255 are stacked vertically (in the z-direction), and capacitor dielectric 255 can be sandwiched between first and second electrodes 253 and 257. In some implementations, each first electrode 253 is coupled to the source or drain of a respective vertical transistor 242 in the same DRAM cell, while all second electrodes 257 are parts of a common plate 265 coupled to the ground, e.g., a common ground.

In some implementations, first electrodes 253 and/or the second electrode 257 can include conductive materials including, but not limited to, W, Co, Cu, Al, TiN, TaN, polysilicon, silicide, or any combination thereof. In some implementations, first electrodes 253 and/or second electrode 257 include a multiple-layer structure, each layer of the multiple-layer structure comprising one of TiN, TaN, carbon, polysilicon, metal, metal compounds, and silicide. For example, as shown in FIG. 2, second electrode 257 includes a first layer 261 coupled with capacitor dielectric 255 directly, a second layer 262 surrounded by first layer 261, and a third layer 263 surrounded by second layer 262. In some implementations, the material of each layer of the multiple-layer structure is different from the material of other layers. For example, first layer 261 is TiN, second layer 262 is carbon, and third layer 263 is W. In some implementations, capacitor dielectric 255 includes dielectric materials, such as silicon oxide, silicon nitride, or high-k dielectrics including, but not limited to, Al₂O₃, HfO₂, Ta₂O₅, ZrO₂, TiO₂, or any combination thereof.

In some implementations, capacitors 244 have a relatively large height and require mechanical stabilization with at least one mesh layer 260, as shown in FIG. 2. As such, the spacing between capacitors 244 remains consistent, thereby preventing capacitor corruption. Without mesh layers 260, the capacitors would lean over and come in to contact with adjacent capacitors. Mesh layer 260 includes larger dielectric materials with a Mohs scale larger than that of silicon oxide, which has a Mohs scale around six. In some implementations, mesh layer 260 can be silicon nitride, silicon carbide, corundum, boron carbide, boron nitride, or any combination thereof. In some implementations, as the aspect ratio of the capacitors 409 increases, two or more levels of mesh are required to ensure mechanical stability.

As shown in FIG. 2, in some implementations, vertical transistors 242 are disposed vertically between capacitors 244 and bonding interface 230. That is, vertical transistors 242 can be arranged closer to peripheral circuits 204 of first semiconductor structure 210 and bonding interface 230 than capacitors 244. Since bit lines 217 and capacitors 244 are coupled to opposite ends of vertical transistors 242, as described above, bit lines 217 (as part of interconnect layer 212) are disposed vertically between vertical transistors 242 and bonding interface 230, according to some implementations. As a result, interconnect layer 212 including bit lines 217 can be arranged close to bonding interface 230 to reduce the routing distance and the complexity of the interconnects.

As shown in FIG. 2, second semiconductor structure 220 can further include a pad-out interconnect layer 270 above DRAM cells 240. Pad-out interconnect layer 270 can include interconnects, e.g., contact pads 272, in one or more ILD layers. Pad-out interconnect layer 270 and interconnect layer 212 can be formed on opposite sides of DRAM cells 240. Capacitors 244 are disposed vertically between vertical transistors 242 and pad-out interconnect layer 270, according to some implementations. In some implementations, the interconnects in pad-out interconnect layer 270 can transfer electrical signals between semiconductor device 200 and external circuits, e.g., for pad-out purposes. In some implementations, second semiconductor structure 220 further includes one or more contacts 274 extending through a portion of pad-out interconnect layer 270 to establish connections between pad-out interconnect layer 270 and interconnect layer 212. Peripheral circuits 204 can be coupled to DRAM cells 240 through interconnect layers 206 and 212, as well as bonding layers 215 and 207. Peripheral circuits 204 and DRAM cells 240 can be coupled to external circuits through contacts 274 and pad-out interconnect layer 270. Contact pads 272 and contacts 274 can include conductive materials including, but not limited to, W, Co, Cu, Al, silicides, or any combination thereof. In one example, contact pad 272 may include Al, and contact 274 may include W.

It is understood that the vertical transistors 242 in DRAM cells 240 are not limited to single-gate transistors as shown in FIG. 2 and may be double-gate transistors or gate-all-around transistors, the structure of which will be detailed below.

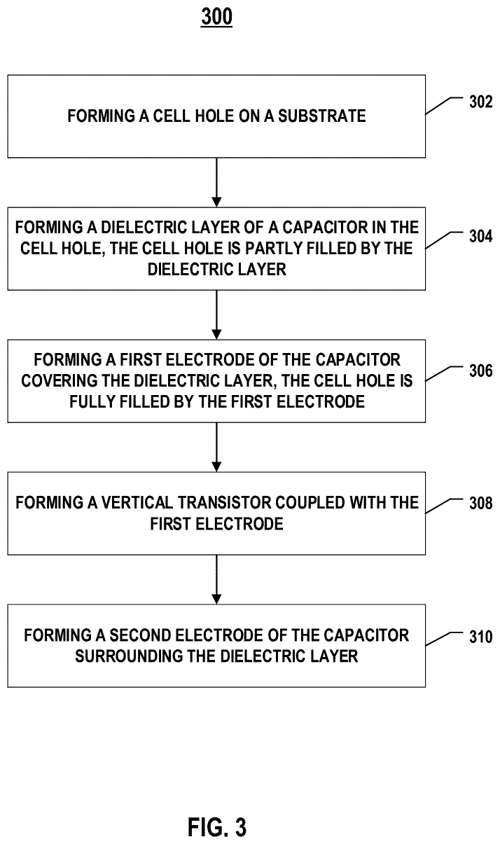

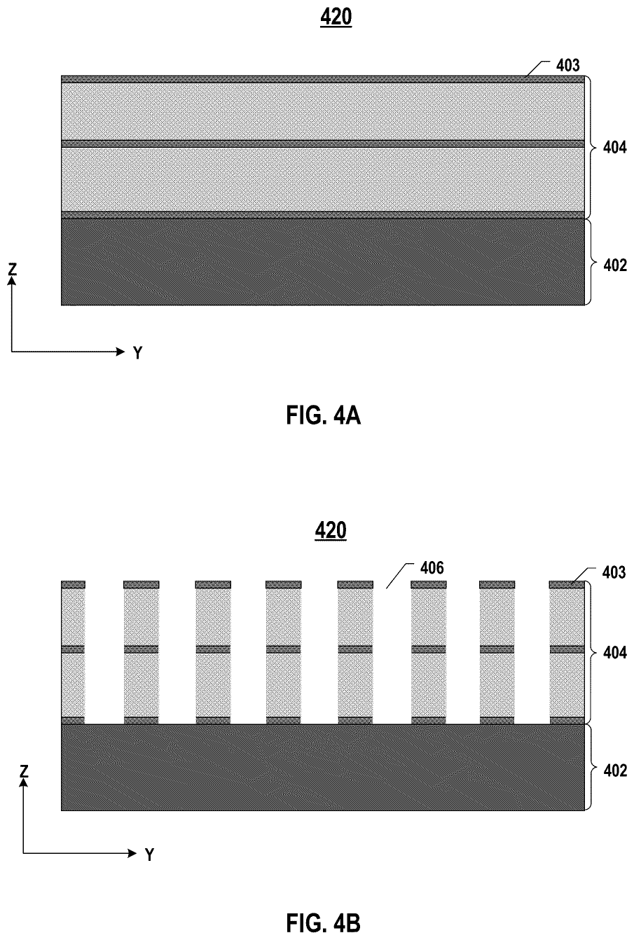

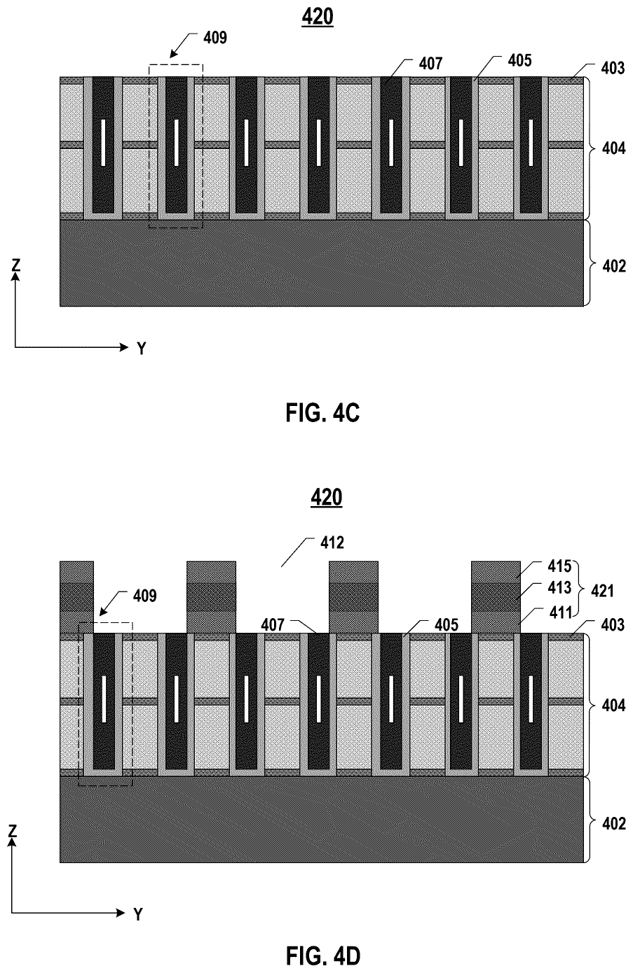

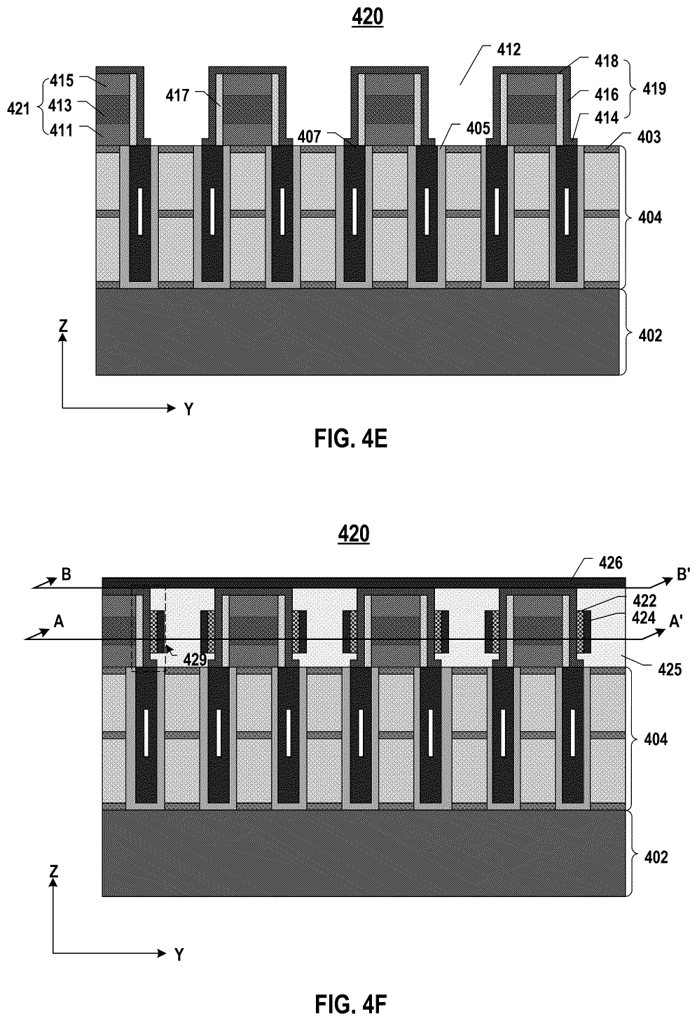

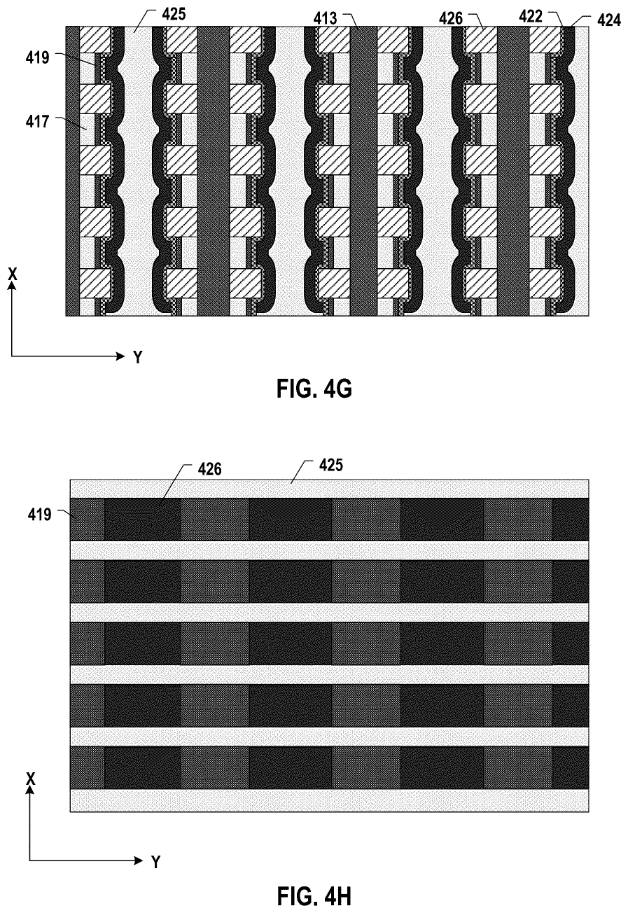

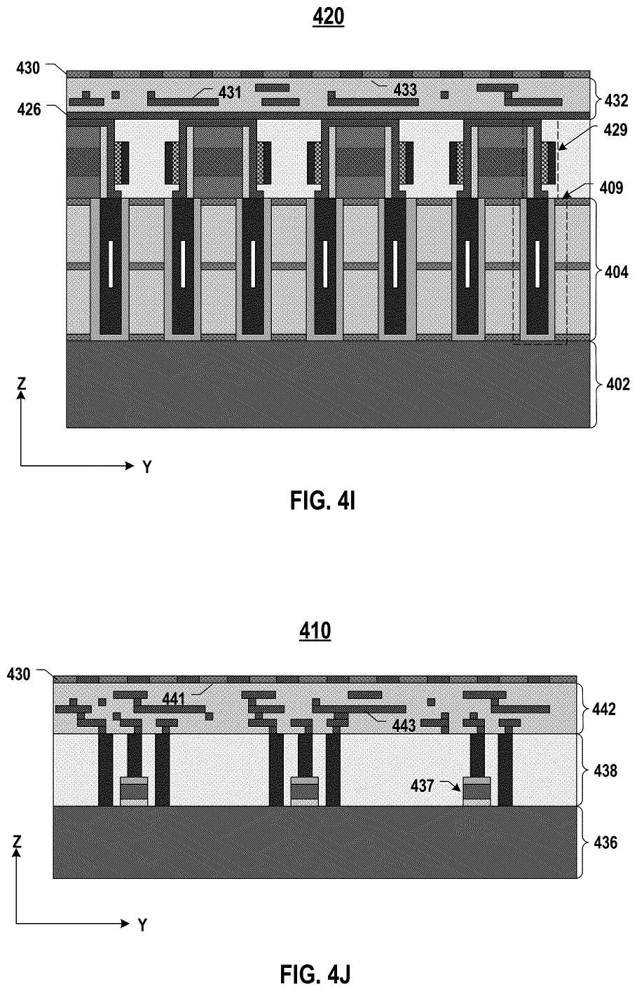

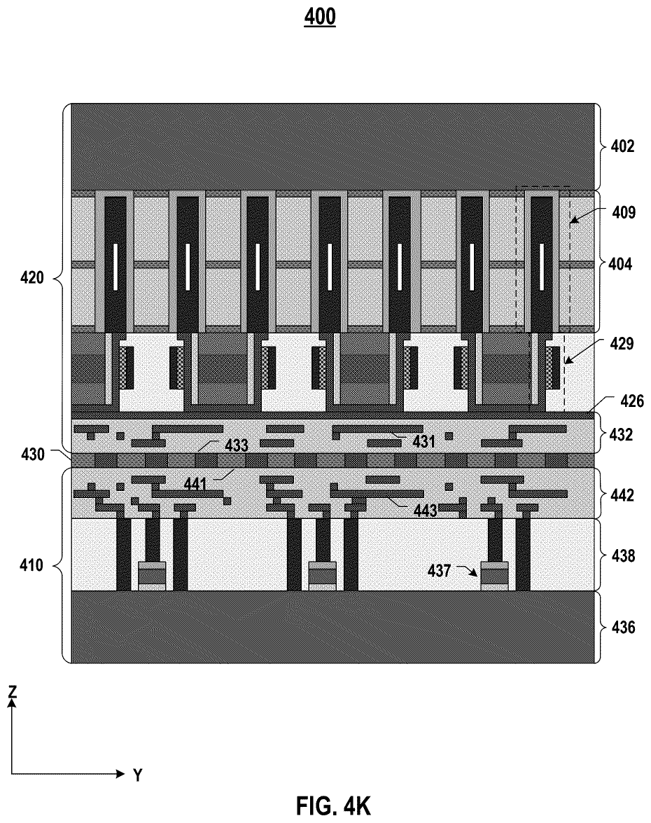

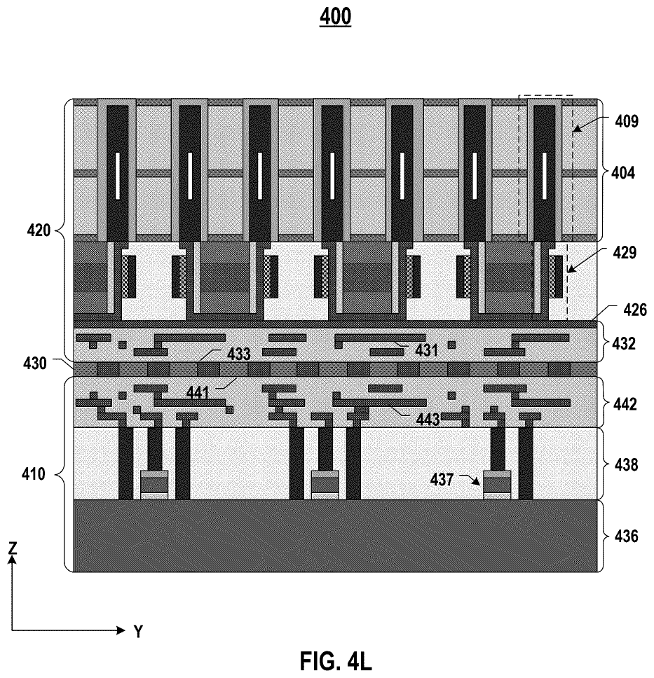

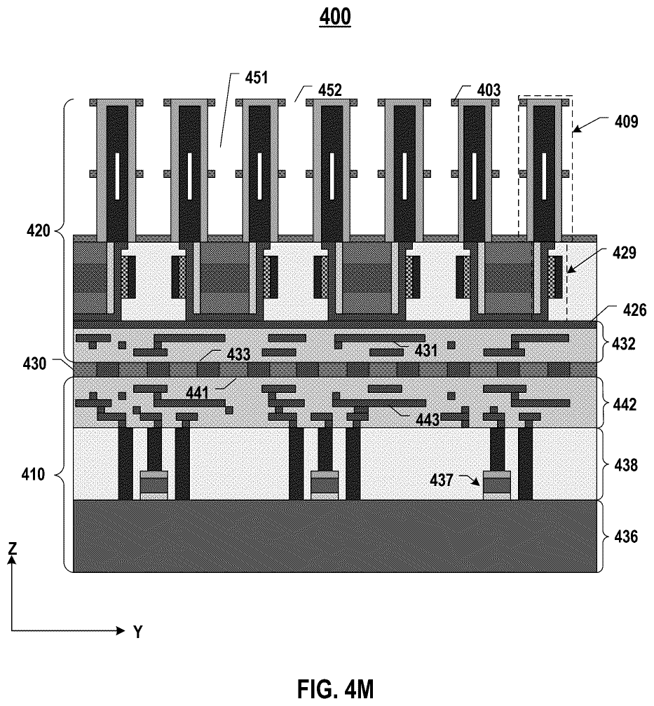

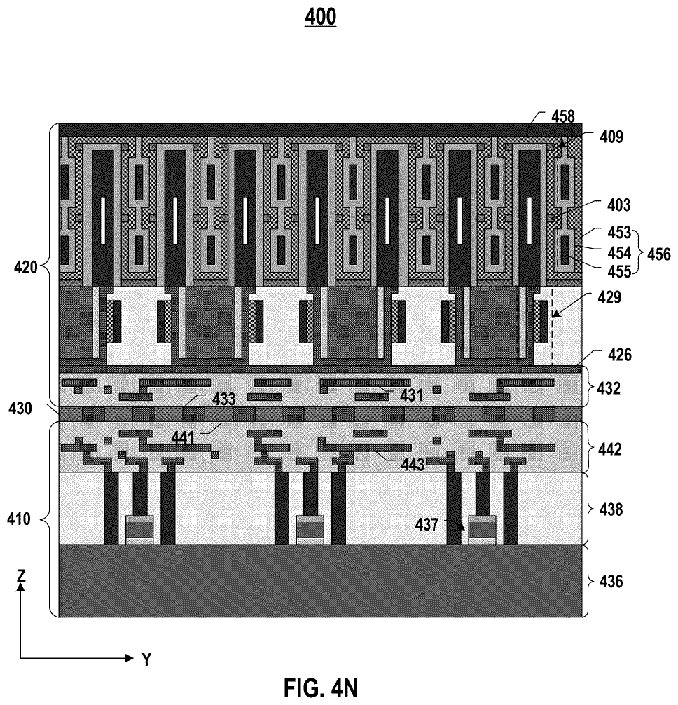

FIG. 3 illustrates a flowchart of a fabricating method 300 for forming a semiconductor device including vertical transistors, according to some implementations of the present disclosure. FIGS. 4A-40 illustrate schematic views of a semiconductor device 400 at certain fabricating stages of the method 300 shown in FIG. 3, according to various implementations of the present disclosure. It is understood that the operations shown in method 300 are not exhaustive and that other operations can be performed as well before, after, or between any of the illustrated operations. Further, some of the operations may be performed simultaneously, or in a different order than shown in FIG. 3.

As shown in FIG. 3, method 300 can start at operation 302 to form a second semiconductor structure 420 including a memory cell array. At operation 302, an array of capacitors 409 can be formed on a substrate 402. FIGS. 4A-4C illustrate schematic side cross-sectional views of the 3D semiconductor device in y-z plane at a certain fabricating stage of operation 302 of method 300.

In some implementations, as shown in FIG. 4A, in which a substrate including a first substrate 402 and a second substrate 404 is formed. In some implementations, first substrate 402 can be a semiconductor substrate, which can include silicon (e.g., single crystalline silicon, c-Si), silicon germanium (SiGe), gallium arsenide (GaAs), germanium (Ge), silicon-on-insulator (SOI), or any other suitable materials. In some other implementations, first substrate 402 can be a carrier substrate, which can include any suitable semiconductor materials, or an electrically non-conductive material, such as a glass, a plastic, or a sapphire wafer. In some implementations, first substrate 402 can be omitted. Second substrate 404 is formed on the first substrate 402 to define a region in which capacitors 409 to be formed in a subsequent process. Second substrate 404 may be any suitable material that is different from the dielectric layer of capacitors 409.

In some implementations, capacitors 409 have a relatively large height and need to be mechanically stabilized with at least one mesh layer 403, as shown in FIG. 4A and FIG. 4B. As such, the spacing between capacitors 409 remains consistent, thereby avoiding capacitor corruption. Without mesh layer 403, the capacitors would lean over and come in to contact with adjacent capacitors. Mesh layer 403 includes larger dielectric materials with a Mohs scale larger than that of silicon oxide, which has a Mohs scale around six. In some implementations, mesh layer 403 has a different material form second substrate 404 and can be silicon nitride, silicon carbide, corundum, boron carbide, boron nitride, or any combination thereof. In some implementations, at least one mesh layer 403 is laminated with at least one dielectric layer alternately. In some implementations, as the aspect ratio of the capacitors 409 increases, two or more mesh layers 403 are required to ensure mechanical stability, as shown in FIG. 4B. In some implementations, a plurality of cell holes 406 are then formed in second substrate 404, and each cell hole 406 penetrates second substrate 404 to expose first substrate 402.

As shown in FIG. 3, method 300 can proceed to operation 304, in which a dielectric layer 405 of capacitor 409 is formed in cell hole 406 and cell hole 406 is partly filled by dielectric layer 405. Method 300 can then proceed to operation 306, in which a first electrode 407 of the capacitor 409 is formed to cover dielectric layer 405 of capacitor 409, and cell hole 406 is fully filled by first electrode 407. FIG. 4C illustrates a schematic side cross-sectional view of the second semiconductor structure 420 in y-z plane after operation 306 of method 300.

In some implementations, dielectric layer 405 includes dielectric materials, such as silicon oxide, silicon nitride, or high-k dielectrics including, but not limited to, Al₂O₃, HfO₂, Ta₂O₅, ZrO₂, TiO₂, or any combination thereof. It should be noted that dielectric layer 405 has a different material from second substrate 404. The dielectric layer 405 of capacitor 409 may be formed by one or more thin film deposition processes including, but not limited to, chemical vapor deposition (CVD), physical vapor deposition (PVD), atomic layer deposition (ALD), or any combination thereof. In some implementations, first electrode 407 can include conductive materials including, but not limited to, W, Co, Cu, Al, TIN, TaN, polysilicon, silicide, or any combination thereof. In some implementations, dielectric layer 405 and first electrode 407 can be formed by a series of fabricating processes including thin film deposition processes (e.g., CVD, PVD, ALD, etc.) and patterning processes (e.g., photoetching, dry etching, wet etching, cleaning, chemical mechanical polishing (CMP), etc.) It is noted that, the fabricating processes and/or orders of forming dielectric layer 405 and first electrode 407 can be varied depending on a front side process or a back side process.

As shown in FIG. 3, method 300 can proceed to operation 308, in which a vertical transistor 429 is formed on the array of capacitors 409 to couple with first electrode 407. FIG. 4E illustrates a schematic side cross-sectional view of the semiconductor device in y-z plane after operation 308 of method 300.

In some implementations, a multiple-layer structure including a conductor layer is formed on the array of capacitors 409 to form an isolation structure 421 between two adjacent transistors, as shown in FIG. 4D. In some implementations, multiple-layer structure includes a first dielectric layer 411, a conductor layer 413 covering first dielectric layer 411, and a second dielectric layer 415 covering conductor layer 413. In some implementations, first dielectric layer 411 and second dielectric layer 415 can include dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, conductor layer 413 can include conductive materials including, but not limited to, W, Co, Cu, Al, TiN, TaN, polysilicon, silicide, or any combination thereof. First dielectric layer 411, conductor layer 413, and second dielectric layer 415 can be formed by a series of fabricating processes including thin film deposition processes such as CVD, PVD, ALD, etc.

In some implementations, a plurality of isolation trenches 412 are then formed on the multiple-layer structure to separate the multiple layer structure into a plurality of isolation structures 421, as shown in FIG. 4D. Isolation trenches 412 penetrate the multiple-layer structure to expose top ends of capacitors 409. Referring to FIG. 4D, two adjacent capacitors 409 are exposed through a same isolation trench 412. In some other implementations, each isolation trench 412 is configured to expose one corresponding capacitor 409 (not shown in figure). In some implementations, two sidewalls 417 are formed to cover a left side and a right side of each isolation structure 421. Referring to FIG. 4E, a left sidewall 417 is formed on the left of conductor layer 413 to separate conductor layer 413 from a first vertical transistor on the left, and a right sidewall 417 is formed on the right of the conductor layer 413 to separate the conductor layer 413 from a second vertical transistor on the right. In some implementations, first dielectric layer 411, second dielectric layer 415, and sidewalls 417 can include different materials such as silicon oxide, silicon nitride, or high-k dielectrics including, but not limited to, Al₂O₃, HfO₂, Ta₂O₅, ZrO₂, TiO₂, or any combination thereof. In such implementations, conductor layer 413 can be surrounded by dielectric layers on all sides to isolate it from adjacent vertical transistors. The plurality of conductor layers 413 are connected to a common grand so that no charge can be accumulated between two adjacent vertical transistors. In this way, electrical coupling between semiconductor layers 419 of two adjacent vertical transistors can be greatly reduced. In some implementations, conductor layer 413 includes conductive materials including, but not limited to W, Co, Cu, Al, TIN, TaN, polysilicon, silicide, or any combination thereof. In some implementations, conductor layer 413 includes multiple conductive layers, such as a W layer over a TiN layer.

In some implementations, a semiconductor layer 419 is formed on isolation structure 421, as shown in FIG. 4E. In some implementations, the semiconductor can be one or more of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O, etc. In some implementations, semiconductor layer 419 can be formed from a deposition process. For example, a semiconductor layer can be formed on covering both isolation structures 421 and isolation trenches 412 by a deposition process, followed by a photolithography process to remove a portion of the semiconductor layer covering a bottom of isolation trenches 412, forming the plurality of semiconductor layer 419 covering the isolation trenches. In some implementations, the semiconductor layer covering capacitors 409 remains during the photolithography process to form an extending portion of semiconductor layer 419. As shown in FIG. 4E, semiconductor layer 419 is isolated from conductor layer 413 by first dielectric layer 411, second dielectric layer 415, and sidewalls 417 between conductor layer 413 and semiconductor layer 419.

Referring to FIG. 4E, semiconductor layer 419 of each vertical transistors 429 includes a vertical portion 416 extending in a vertical direction (z-direction), a first lateral portion 418 extending from a first end of vertical portion 416 in a lateral direction (y-direction), and a second lateral portion 414 extending from a second end of vertical portion 416 in the lateral direction (y-direction). The second lateral portion 414 is coupled with the corresponding capacitor 409. Referring to FIG. 4E, first lateral portion 418, vertical portion 416, and second lateral portion 414 are formed as a whole during the fabrication process. As shown in FIG. 4E, each semiconductor layer 419 formed in the corresponding isolation trench 412 has a U-shaped cross-section in y-z plane. The U-shaped semiconductor layer 419 includes vertical portion 416 of a first vertical transistor covering the left sidewall 417, first lateral portion 418 of the first vertical transistor covering second dielectric layer 415, vertical portion 416 of a second vertical transistor covering the right sidewall 417, and first lateral portion 418 of the second vertical transistor covering second dielectric layer 415. In some implementations, the U-shaped semiconductor layer 419 further includes second lateral portions 414 of the first and second vertical transistors. In some implementations, before forming semiconductor layer 419, first electrode 407 is etched back to form a recess, and second lateral portion 414 can then be formed in the recess. In this way, an edge is created between the semiconductor layer in the recess and the other portion of semiconductor layer covering the bottom of isolation trench. The subsequent photolithography can be eased as the edge is detectable and can be used as a mark during alienation of a mask and the semiconductor layer.

Gate dielectric layer 422 can be formed to cover semiconductor layer 419, in the present implementation. Gate dielectric layer 422 can include any suitable dielectric materials, such as silicon oxide, silicon nitride, silicon oxynitride, or high-k dielectrics. For example, gate dielectric layer 422 may include silicon oxide, i.e., gate oxide, which can be formed during the fabricating of gate electrode 424. In some implementations, gate dielectric layer 422 can be high-k dielectrics including, but not limited to, Al₂O₃, HfO₂, Ta₂O₅, ZrO₂, TiO₂, or any combination thereof. Gate electrode 424 can be formed to cover gate dielectric layer 422. Gate electrode 424 can include any suitable conductive materials, such as polysilicon, metals (e.g., W, Cu, Al, etc.), metal compounds (e.g., TiN, TaN, etc.), or silicide. For example, gate electrode 424 may include doped polysilicon, i.e., a gate poly. In some implementations, gate electrode 424 includes multiple conductive layers, such as a W layer over a TiN layer. An isolation layer 425 is then formed to fill the space between the vertical transistors 429 as shown in FIG. 4F. As described below with respect to the fabrication process, air gaps may be formed in isolation layer 425 between adjacent vertical transistors (not shown in figures). The relatively large dielectric constant of air in the air gap can improve the insulation effect between vertical transistors 429 compared with some dielectrics (e.g., silicon oxide).

In some implementations, a plurality of bit lines 426 and word lines 424 (referred to as gate electrodes 424 as well) can be formed on the array of vertical transistors 429. FIG. 4F illustrates a schematic side cross-sectional view of the semiconductor device in y-z plane after the formation of bit lines 426. FIG. 4G illustrates a schematic cross-sectional view cut along AA′ direction of the semiconductor device in the x-y plane. FIG. 4H illustrates a schematic cross-sectional view cut along BB′ direction of the semiconductor device in the x-y plane. Vertical transistor 429 extends vertically and is coupled with a corresponding word line 424. First lateral portion 418 of semiconductor layer 419 of vertical transistor 429 is coupled with bit line 426. As shown in FIG. 4H, bit lines 426 can be formed directly on isolation layer 425 and first lateral portion 418 of semiconductor layer 419 of vertical transistor 429. Different from the formation of bit lines coupled with vertical portion 416, bit lines 426 in the present disclosure can be formed through a deposition process without the need to etch isolation layer 425. This approach can significantly decrease fabricating complexity and cost associated with the inclusion of first lateral portion 418.

In some implementations, referring to FIG. 4I to FIG. 4K, second semiconductor structure 420 is bonded with a first semiconductor structure 410, which contains a peripheral circuit, to form semiconductor device 400 through hypoid bonding. As shown in FIG. 4I, second semiconductor structure 420 can also include an interconnect layer 432 including a bonding layer 433 at bonding interface 430 to be coupled to a bonding layer of a first semiconductor structure 410. Bonding layer 433 can include a plurality of bonding contacts 431 and dielectrics electrically isolating bonding contacts 431. Bonding contacts 431 can include conductive materials, such as Cu. The rest areas of bonding layer 433 surrounding bonding contacts 431 can include dielectric materials, such as silicon oxide. Bonding contacts 431 and surrounding dielectrics in bonding layer 433 can be used for hybrid bonding. Bonding contacts 431 are coupled with the bonding contacts of first semiconductor structure 410 at bonding interface 430, according to some implementations. First semiconductor structure 410 can include peripheral circuits 438 on substrate 436. In some implementations, peripheral circuits 438 include a plurality of transistors 437 (e.g., planar transistors and/or semiconductor transistors). Trench isolations (e.g., shallow trench isolations (STIs)) and doped regions can be formed either on or within substrate 436. In some implementations, first semiconductor structure 410 further includes an interconnect layer 442 under peripheral circuits 438 to transfer electrical signals to and from peripheral circuits 438. Interconnect layer 442 can include a plurality of interconnects (also referred to herein as “contacts”), including lateral interconnect lines and vertical interconnect access (VIA) contacts. As used herein, the term “interconnects” can broadly include any suitable types of interconnects, such as middle-end-of-line (MEOL) interconnects and back-end-of-line (BEOL) interconnects. Interconnect layer 442 can further include one or more interlayer dielectric (ILD) layers (also known as “intermetal dielectric (IMD) layers”), in which the interconnect lines and via contacts are situated. That is, interconnect layer 442 can include interconnect lines and via contacts in multiple ILD layers. In some implementations, peripheral circuits 438 are coupled to one another through the interconnects in interconnect layer 442. The interconnects in interconnect layer 442 can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

As shown in FIGS. 4J and 4K, first semiconductor structure 410 can further include a bonding layer 441 at bonding interface 430 and above interconnect layer 442 and peripheral circuits 438. Bonding layer 441 can include a plurality of bonding contacts 443 along with dielectrics that electrically isolate bonding contacts 443. Bonding contacts 443 can include conductive materials, such as Cu. The rest of the areas of bonding layer 441 can be formed with dielectric materials, such as silicon oxide. Bonding contacts 443 and surrounding dielectrics in bonding layer 441 can be used for hybrid bonding.

As shown in FIG. 3, method 300 can proceed to operation 310, in which a second electrode 456 of capacitor 409 is formed to surround dielectric layer 405 of capacitor 409, as shown in FIG. 4L to FIG. 4N.

FIG. 4L illustrates a schematic side cross-sectional view of semiconductor device 400 in the y-z plane after substrate 402 is removed to expose the bottom of second substrate 404. In some implementations, mesh layer 403 at the bottom of second substrate 404 is exposed, as shown in FIG. 4L. Then referring to FIG. 4M, a plurality of openings 452 are formed on mesh layer 403 to expose the dielectric layer of second substrate 404. Since the dielectric layer of second substrate 404 has a different material than mesh layer 403, the dielectric layer can be easily removed to form a cavity 451 through wet etching. In some implementations, there may be more than two mesh layers formed in the second substrate 404. For example, as shown in FIG. 4M, three mesh layers 403 are formed in second substrate 404, with two dielectric layers sandwiched among the mesh layers 403. In such implementations, openings 452 can be formed on a second mesh layer after the removal of a first dielectric layer, and then a second dielectric layer can then be removed through the openings in the second mesh layer in a similar manner. As shown in FIG. 4M, dielectric layers 405 are exposed from the cavities 451.

FIG. 4N illustrates a schematic side cross-sectional view of semiconductor device 400 in the y-z plane after the formation of second electrode 456. In some implementations, second electrode 456 can include conductive materials including, but not limited to, W, Co, Cu, Al, TIN, TaN, polysilicon, silicide, or any combination thereof. In some implementations, second electrode 456 includes a multiple-layer structure, where each layer of the multiple-layer structure comprises one of TiN, TaN, carbon, polysilicon, metal, metal compounds, and silicide. For example, as shown in FIG. 4N, second electrode 456 includes a first layer 453 directly coupled with capacitor dielectric 405, a second layer 454 surrounded by first layer 453, and a third layer 455 surrounded by second layer 454. In some implementations, the material of each layer of the multiple-layer structure differs from that of the other layers. For example, first layer 453 is TIN, second layer 454 is carbon, and third layer 455 is W. In some implementations, a common plate 458 is formed on the array of capacitors 409, and the second electrodes 456 are directly coupled to the common plate 458. In some implementations, the formation of second electrodes 456 can involve a series of fabricating processes, including thin film deposition processes and patterning processes.

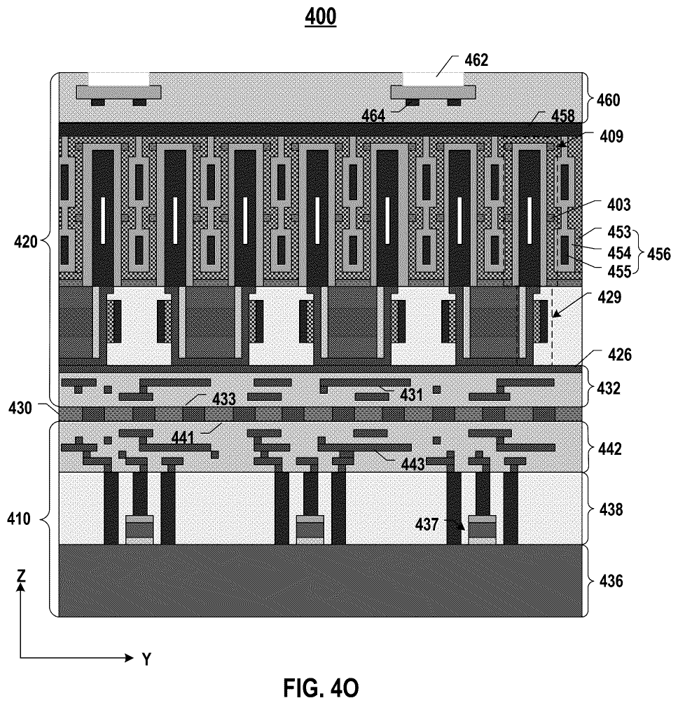

In some implementations, a pad-out interconnect layer 460 is formed. FIG. 40 illustrates a schematic side cross-sectional view of semiconductor device 400 in the y-z plane after pad-out interconnect layer 460 being formed on common plate 458. Pad-out interconnect layer 460 can include interconnects, e.g., contact pads 462, arranged in one or more ILD layers. Pad-out interconnect layer 460 and first semiconductor structure 410 can be formed on a same side of second semiconductor structure 420. In some implementations, the interconnects in pad-out interconnect layer 460 can transfer electrical signals between the semiconductor device and external circuits, e.g., for pad-out purposes. In some implementations, second semiconductor structure 420 further includes one or more contacts 464 to connect pad-out interconnect layer 460 to DRAM cells (e.g., vertical transistors 429 and capacitors 409). Contact pads 462 and contacts 464 can include conductive materials including, but not limited to, W, Co, Cu, Al, silicide, or any combination thereof. In one example, contact pad 462 may include Al, and contact 464 may include W.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described implementations but should be defined only in accordance with the following claims and their equivalents.

What is claimed is:

1. A semiconductor device, comprising vertical transistors and storage units coupled with the vertical transistors correspondingly, wherein
the vertical transistor comprises:
a semiconductor layer comprising a vertical portion extending in a vertical direction and a first lateral portion extending from a first end of the vertical portion in a lateral direction, and
a gate structure coupled to the vertical portion of the semiconductor layer and extending in the vertical direction; and
the first lateral portions of the semiconductor layers of two adjacent vertical transistors in the lateral direction are connected with each other.

2. The semiconductor device of claim 1, wherein
the semiconductor layer has a U-shaped cross-section in a plane formed by the vertical direction and the lateral direction.

3. The semiconductor device of claim 1, wherein
the semiconductor layer of the vertical transistor comprises a second lateral portion extending from a second end of the vertical portion in the lateral direction, and the second lateral portion is coupled with the corresponding storage unit.

4. The semiconductor device of claim 3, wherein
the storage unit comprising a capacitor with a first electrode, a second electrode, and a dielectric layer between the first electrode and the second electrode; and
the first electrode is directly coupled with the second lateral portion of the semiconductor layer of the corresponding vertical transistor.

5. The semiconductor device of claim 1, wherein
two adjacent vertical transistors in the lateral direction are separated by an isolation structure, and the gate structure of the vertical transistor is positioned in a side of the vertical portion of the semiconductor layer opposite to the isolation structure.

6. The semiconductor device of claim 5, wherein the isolation structure comprises:
a conductor layer; and
a dielectric layer surrounding the conductor layer.

7. The semiconductor device of claim 6, wherein the dielectric layer comprises:
a first dielectric layer under the conductor layer;
a second dielectric layer on the conductor layer;
a left sidewall on the left of the conductor layer to separate the conductor layer from a first vertical transistor on the left; and
a right sidewall on the right of the conductor layer to separate the conductor layer from a second vertical transistor on the right.

8. The semiconductor device of claim 1, further comprising:
bit lines extending in the lateral direction and directly coupled with the vertical transistors through the first lateral portions of the semiconductor layers of the vertical transistors.

9. The semiconductor device of claim 1, wherein
the semiconductor layer has a leakage value lower than a pico-ampere.

10. A method for forming a semiconductor device, comprising:
forming a cell hole on a substrate;
forming a dielectric layer of a capacitor in the cell hole, the cell hole is partly filled by the dielectric layer;
forming a first electrode of the capacitor covering the dielectric layer, the cell hole is fully filled by the first electrode;
forming a vertical transistor coupled with the first electrode; and
forming a second electrode of the capacitor surrounding the dielectric layer.

11. The method of claim 10, wherein
the substrate comprises at least one mesh layer laminated with at least one sacrifice layer alternately; and
forming the second electrode of the capacitor comprises:
removing the at least one sacrifice layer to form a cavity; and
filling the cavity with the second electrode of the capacitor.

12. The method of claim 11, wherein filling the cavity with the second electrode of the capacitor comprise:
forming a multiple-layer structure in the cavity; and
each layer of the multiple-layer structure comprises one of carbon, polysilicon, metal, metal compounds, and silicide.

13. The method of claim 10, wherein forming the vertical transistor coupled with the first electrode comprises:
forming an isolation structure between two adjacent vertical transistors.

14. The method of claim 13, wherein forming the isolation structure between two adjacent vertical transistors comprises:
forming a first dielectric layer on the substrate;
forming a conductor layer on the first dielectric layer; and
forming a second dielectric layer on the conductor layer.

15. The method of claim 13, wherein forming the isolation structure between two adjacent vertical transistors further comprises:
forming a left sidewall on the left of conductor layer to separate the conductor layer from a first vertical transistor on the left; and
forming a right sidewall on the right of the conductor layer to separate the conductor layer from a second vertical transistor on the right.

16. The method of claim 15, wherein forming a vertical transistor coupled with the first electrode comprises:
forming a semiconductor layer covering the isolation structure; and
the semiconductor layer has a U-shaped cross-section in a plane formed by a vertical direction and a lateral direction.

17. The method of claim 16, wherein the semiconductor layer comprises:
a vertical portion of the first vertical transistor covering the left sidewall;
a first lateral portion of the first vertical transistor covering a second dielectric layer;
a vertical portion of the second vertical transistor covering a right sidewall; and
a first lateral portion of the second vertical transistor covering the second dielectric layer.

18. The method of claim 17, further comprising:
forming a bit line extending in a lateral directly coupled with the vertical transistors through the first lateral portions of the semiconductor layers of the vertical transistors.

19. The method of claim 17, wherein
the semiconductor layer has a leakage value lower than a pico-ampere.

20. A semiconductor device, comprising single-gate vertical transistors and storage units coupled with the single-gate vertical transistors correspondingly, wherein
two adjacent single-gate vertical transistors in a lateral direction are separated by an isolation structure and share a U-shaped semiconductor layer covering both sides of the isolation structure in the lateral direction; and
a gate structure of the single-gate vertical transistor is coupled with a side of the semiconductor layer opposite to the isolation structure.
